(19) United States
(12) Patent Application Publication
(10) Pub. No.: US 2001/0031374 A1
(43) Pub. Date: Oct. 18, 2001

(54) Magnetic film having a magnetic easy-axis or a multiple easy-axis and a method of manufacturing the magnetic film

(76) Inventors: Chung Nam Whang, Seoul (KR); Gap Soo Chang, Tae Gu Gwang Yeok Shi (KE); Keun Hwa Chae, Seoul (KR); Kwang Ho Jeong, Seoul (KR)

Correspondence Address: BIRCH STEWART KOLASCH & BIRCH, PO BOX 747, FALLS CHURCH, VA, 22040-0747, US

(21) Appl. No.: 09/828,819

(22) Filed: Apr. 10, 2001

(30) Foreign Application Priority Data
Apr. 12, 2000 (KR) 2000-019153

(51) Int. Cl. H01F 10/12; C23C 14/04; B32B 15/04; G11B 5/716; G11B 5/706; C23C 14/48

(52) U.S. Cl. 428/607; 427/526; 428/630; 428/336; 428/694 TM; 428/694 TS

(57) ABSTRACT

The present invention relates to a magnetic film having a magnetic easy axis in a preformed area, and a method of forming the magnetic film Especially, the present invention relates to a method of forming a multiple magnetic easy-axis in a preformed magnetic film and a magnetic film having multiple easy-axis by the same method of forming the multiple easy axis. It is an object of the present invention to overcome the drawbacks of the conventional magnetic film and to achieve ultrahigh density of the unit recording cells using the magnetic film. It is another object of the present invention to suggest a method of forming a magnetic film and a magnetic film device in which the exchange interaction and the magneto-static interaction between the neighboring areas are eliminated in order to accomplish ultrahigh density for storing data, The present invention presents first, a magnetic film (or area) having a magnetic easy axis and a method of forming a magnetic easy axis on the magnetic film. The magnetic moments of the magnetic area having an easy axis are automatically aligned to the axis without an external magnetic field. This means that the magnetic moments of the magnetic area having an easy axis are strictly limited to the state in which the easy axis is same in magnitude but opposite in directions. Second, this invention presents a magnetic thin film having two neighboring areas with different direction of easy axis in each area so that the exchange interaction between the two neighboring areas is greatly reduced or eliminated.

### BACKGROUND OF THE INVENTION

1. Field of the Invention

The present invention relates to a magnetic film having a magnetic easy axis in a preformed area, and a method of forming the magnetic film. Especially, the present invention relates to a method of forming a multiple magnetic easy-axis in a pre-formed magnetic film and a magnetic film having multiple easy-axis by the same method of forming the multiple easy axis.

2. Description of the Related Art

Information treatment technology has improved steadily during the last decade. Living in the information era, peoples need and demand in obtaining and storing information continues to grow and people eager for a storage media that will satisfy their needs. Therefore, the need for high density data storage media will increase rapidly and markets will look for manufacturers who have the technology.

There are two kinds of storing systems. One is the primary memory made of semiconductor material such as DRAM, SDRAM, EPROM etc and the other is the secondary memory made of the magnetic material. The primary memory is used for storing data temporarily whereas the secondary memory is used for storing data for a long period of time. In conventional method of storing data using the secondary memory, the data is stored in a magnetic media such as a magnetic tape, magnetic disk and magnetic drum or in an optical media such as a compact disk (CD) system. The disk type magnetic media is most widely used among these devices and it is more popular than the magnetic tape or the magnetic drum. A floppy disk driver (FDD) system, a hard disk driver (HDD) system and a magneto-optical disk driver (MOD) system are the storing systems in disk type magnetic media. The conventional structure of the magnetic media is shown in FIG. 1. An under layer 13 including Cr, CrV, is deposited on a substrate 11 of Al/Mg which is made of alloy Nip seed layer (not shown) or glass with the thickness of 500 Å. A magnetic layer 15 including CoCrPt, CoCrPtB, FePtCr or, CoNiCr is deposited on the under layer 13 with the thickness of 200 Å-300 Å. An overcoat layer 17 with the thickness of 100 Å including C:Nx and a lubricant layer 19 with the thickness of 20 Å are deposited sequentially thereon.

The conventional magnetic media has a continuous magnetic film (or magnetic layer 15). Each bit of information is stored by magnetizing a small region on the continuous thin magnetic film using a write head that provides a suitable magnetic field. A magnetic moment, location and an area of the small region present a bit of binary information and these must be defined precisely to allow a magnetic sensor, called a read head, to retrieve the written information. The conventional magnetic disk storage suffers several drawbacks that hinder realization of ultrahigh density storage. First, the magnetic moments of a continuous film have an infinite number of possibilities. Therefore, the write bead must write very precisely in defining the magnetic moment, the location, and the area of each bit cell (which contains a bit of binary information) on the magnetic film. A slight error in doing so will not only create the error in the bit cell, but also could miswrite the neighboring bit cells, causing errors in reading. Second, a continuous magnetic film is very good at linking exchange interaction and magneto-static interaction between the bit cells. When the bit cells are very close to one another, writing of one bit cell could lead to writing of its neighbors because of the exchange interaction and magneto-static interaction between the bit cells. hird, the continuous magnetic film makes bit cells to have no physical boundaries among them making the reading and writing in a blind fashion. This means that the location of each bit cell is found by calculating the movements of the disk and by writing or reading heads, instead of physically sensing the location of the actual bit cell, Finally, the continuous magnetic film also Has the boundary of two bit cells with different ragged magnetization, creating noise when reading.

In general, the RAM (Random Access Memory) representing the primary memory is made of semiconductor. Therefore, price per unit capacity of the memory is very expensive compared to the hard disk representing the secondary memory. Besides, as almost all kinds of primary memory are volatile, information is erased when the electric power is turned off. There are non-volatile RAM such as SRAM (Static RAM and FRAM (Flash RAM), however, they are more expensive than volatile DRAM (Dynamic RAM). Some developers introduced MRAM (Magnetic RAM) to the market in order to -et a new type of non-volatile RAM with low cost. FIG. 2 shows the general structure of the MRAM. The basic principle of the MRAM comes from the MR (Magnetic Resistance) head. A plurality of word Tine 61 running in one direction is arrayed with a gap. On the each word line 61, a plurality of magnetic bit cell 55 is arrayed, A plurality of bit line 63 running in the other direction crossing the word line 61 is arrayed on the magnetic bit cell 55. That is, the word line 61 and the bit line 63 cross each other in the three dimensional space, and the bit cell 55 is sandwiched at the crossing area of the word line 61 and the bit line 63. Here, the bit cell 55 comprises a first ferromagnetic layer 71 contacting the word line 61, a second ferromagnetic layer 73 contacting the bit line 63 and a tunneling barrier layer 77 inserted between the first 71 and second ferromagnetic layer 73. The first ferromagnetic layer 71 is magnetized in parallel direction to running direction of the word line 61. If the magnetized states of the first 71 and the second ferromagnetic layer 73 are the same, the bit cell represents “0” of digitized value because the current resistance among the bit cells 55 is low. Otherwise, the bit cell represents “1” as the current resistance is high, Therefore, when an electrical current is applied to one of word lines 61, different voltages are detected at the bit lines 63 according to the magnetized state of the bit cells 55. As a result, the stored data is retrieved. Electric current is applied to a selected word line 61 and a selected bit line 63 to write data and the second ferromagnetic layer 73 is magnetized in the reversed direction to the first ferromaagnetic layer 71. The MRAM consists of magnetic materials for memory cells and semiconductor materials for driving the magnetic cells. In the MRAM, increasing the density of the magnetic cells is one of the important problems. The magnetic cells of the MRAM are isolated Tom one another. However, there are the same problems of the exchange interaction and the magneto-static interaction, when the magnetic cells are closely arrayed to increase the areal density.

To achieve ultrahigh density magnetic storage, the drawbacks of the conventional magnetic storage mentioned above must be overcome. Many efforts were put in to overcome the drawbacks and in U.S. Pat. Nos. 5,956,216 and 6,146,755, the overcoming of the drawbacks is illustrated in particular. These two patents suggest discrete magnetic elements of magnetic materials. According to the patents, each discrete magnetic element is separated from other elements by nonmagnetic materials. The spacing is large enough so that exchange interaction between two neighboring elements is either greatly reduced or eliminated. Each magnetic element has a small size and a preferred shape anisotropy so the magnetic moments of each discrete magnetic element are automatically aligned to an axis of the element without an external magnetic field. Such a discrete magnetic element is called a single magnetic domain element. Cost for fabricating the magnetic film having such single domains according to these conventional inventions is very expensive. Accordingly, adaptation in the manufacturing lines and commercialization in the real market are difficult.

### SUMMARY OF WE INVENTION

The inventors filed a patent with KIPO (Korea Intellectual Property Organization) in Jul. 24, 1998 and the application number 10-1998-029830 was assigned. In this application, method of forming a meta-stable magnetic material and a magnetic material thereby is mentioned. It is shown that a thin magnetic film having advanced magnetic properties is obtained by depositing multi layers of earth rare materials and transition elements and by mixing the earth rare materials and transition elements using an ion beam including inert gas in a magnetic field. As a result, the magnetic momentum and coerciveness were improved up to 50% after the ion beam mixing. Studies about the magnetism of the magnetic thin film which is treated with the ion beam are done continuously and it is found out that an easy-axis is formed in a thin magnetic film after the ion beam mixing. This patent further exploits the magnetic film having an easy axis and multiple easy axis.

It is an object of the present invention to overcome the drawbacks of the conventional magnetic film and to achieve ultrahigh density of the unit recording cells using the magnetic film. It is another object of the present invention to suggest a method of forming a magnetic film and a magnetic film device in which the exchange interaction and the magneto-static interaction between the neighboring areas are eliminated in order to accomplish ultrahigh density for storing data The present invention presents first, a magnetic film (or area) having a magnetic easy axis and a method of forming a magnetic easy axis on the magnetic film. The magnetic moments of the magnetic area having an easy axis are automatically aligned to the axis without an external magnetic field. This means that the magnetic moments of the magnetic area having an easy axis are strictly limited to the state in which the easy axis is same in magnitude but opposite in directions. Second, this invention presents a magnetic thin film having two neighboring areas with different direction of easy axis in each area so that the exchange interaction between the two neighboring areas is greatly reduced or eliminated.

### BRIEF DESCRIPTION OF THE DRAWINGS

FIG. 1 is the cross sectional view showing the general structure of the magnetic storage device such as hard disk drive system.

FIG. 2 is the perspective view showing the general structure of the magnetic RAM

FIGS. 3a to 3c show an example of manufacturing method of a meta-stable CoPt alloy having dual easy axis according to the present invention.

FIG. 4 shows the easy axis of the CoPt multi layer, the CoPt meta-stable alloy mixed by an ion beam and the CoPt meta-stable alloy mixed by ion beam within a magnetic field.

FIGS. 5a to 5c show another example of manufacturing method of a ferromagnetic layer having dual easy axis according to the present invention.

FIG. 6 shows the easy axis of the deposited FePt alloy layer, the FePt Alloy layer treated by an ion beam and the FePt alloy layer mixed by ion beam within a magnetic field.

FIG. 7 shows a magnetic force microscope (MFM) image of CoPt alloy or FePt alloy manufactured according to the present invention.

FIGS. 8a and 8b show the third example of manufacturing method of magnetic layer having dual easy axis using geometrical variation according to the present invention.

FIG. 9 shows the easy axis of the magnetic layer of CoPt multi layer, the magnetic layer treated by an ion beam at a first geometric condition and the magnetic layer treated by the ion beam at a second geometric condition.

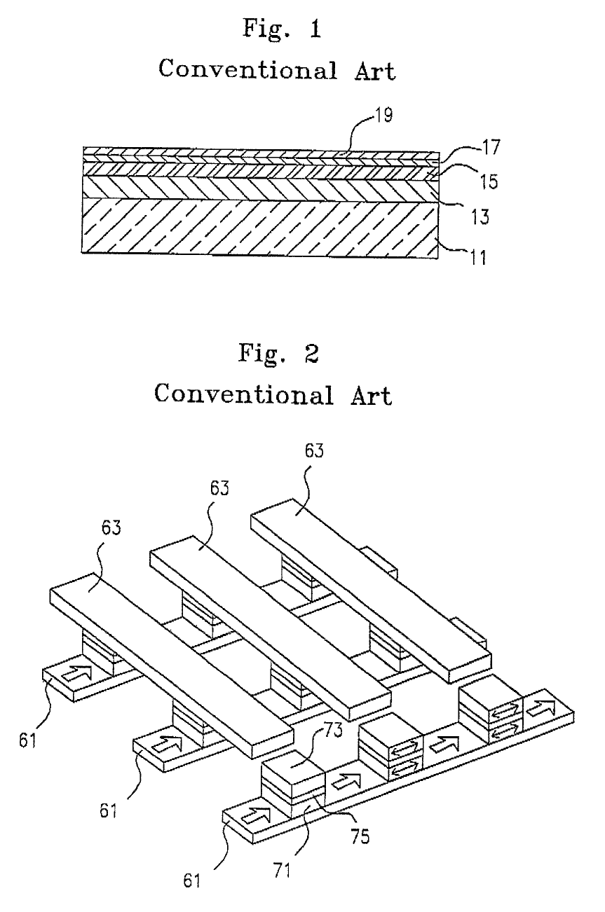

### DETAILED DESCRIPTION OF THE PREFERRED EMBODIMENTS

In the present invention, a magnetic film having a ferromagnetic material such as Co, Ni or Fe is formed on a substrate and the magnetic film is treated with an ion beam having inert gas such as He, Ne, Ar Xe or, Kr to form an easy as. Furthermore, when the ion beam is implanted into the magnetic film, a magnetic field is applied to make another easy axis of which crosses the easy axis formed without the magnetic field. Hereinafter, forming an easy axis or multiple easy axis will be explained in preferred embodiments referring to the attached drawings.

Preferred Embodiment 1

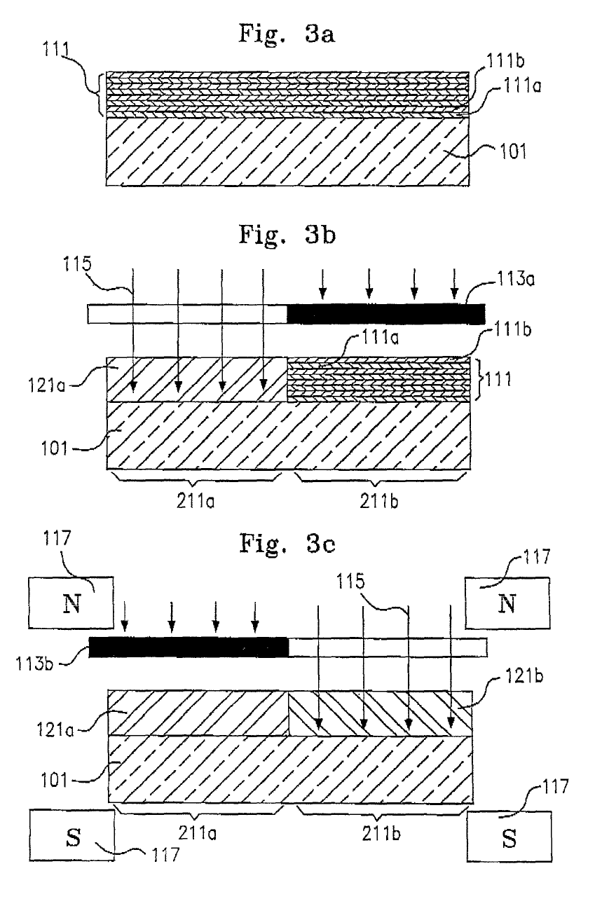

The FIGS. 3a to 3c show a method of forming a meta-stable magnetic material having dual easy axis by an ion beam mixing, In this preferred embodiment, the magnetic material has at least one of earth rare materials such as Pt, Pd, Au and Tb and at least one of transition metals such as Co, Fe, and Ni. The ion beam for King the earth rare materials and the transition metals includes a selected one among inert gases such as He, Ne, Ar, Xe and Kr.

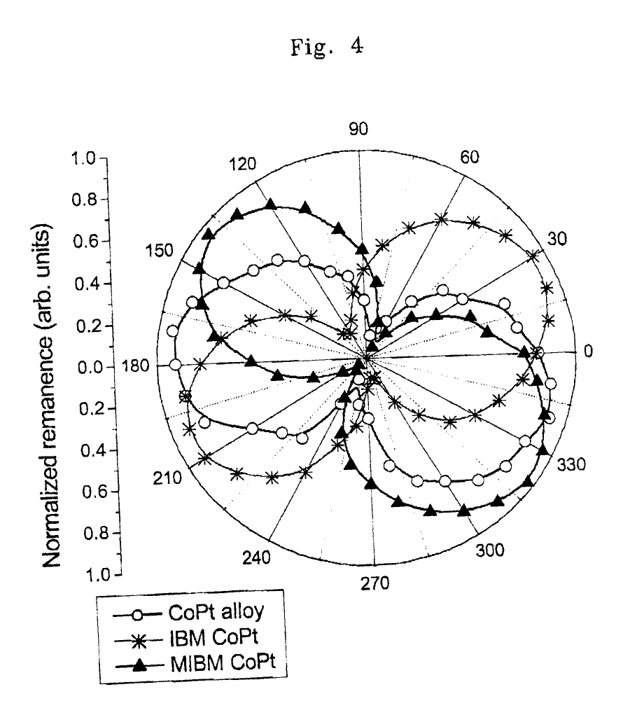

Referring to FIG. 3a, eight Pt layers 111a and eight Co layers 111b are deposited alternatively on a substrate 101 made of glass to form a CoPt multi layer 111b in a vacuum chamber (not shown in figure) with 8×10⁻⁷ torr. The thickness of each Pt layer 111a is 35 Å and that of each Co layer 111b is 45 Å so the thickness of the CoPt multi layer 111 is 640 Å. Here, an easy axis i the Co/Pt multi layer 111 of which direction is formed along to 170°-350° in the polar coordinate system is detected. As shown in FIG. 4, the white circles represent the direction of the easy axis of the CoPt multi layer 111. A first area 211a and a second area 211b are defined in the CoPt multi layer 111.

Referring to FIG. 3b, a second area glib is covered with a first mask 113a such as a stencil mask or a photo resist mask. Using an ion beam generator (not shown), an Ar⁺ ion beam 115 is injected into the first area 211a of the CoPt multi layer 111 where the energy of the ion beam 115 is about 80 keV. Then the Co/Pt multi layer 111 is mixed to form a first meta-stable metal layer 121a having CoPt alloy. The first area 211a has a first easy axis having the direction of 200°-20° in the polar coordinate system. The asterisks, in the FIG. 4, represent the direction of the first easy axis of the CoPt alloy in the fist 211a.

Referring to the FIG. 3c, the first area 211a of the Co/Pt multi layer is covered with a second mask 113b (stencil mask or photo resist mask). A magnetic field is applied to surface of the Co/Pt multi layer in the perpendicular direction using magnets 117. An Ar⁺ ion beam 115 is injected into the second area 211b of the CoPt multi layer using an ion beam generator where the energy of the ion beam 115 is about 80 keV. Then the CoPt multi layer is mixed to form a second meta-stable metal layer 121b having CoPt alloy. The second area 211b has a second easy axis having the direction of about 140°-320° in the polar coordinate system. As shown in FIG. 4, the black triangles represent the direction of the second easy axis of the CoPt alloy in the second area 211b. Therefore, according to FIGS. 3b, 3c and 4, the difference in the direction between the first and second easy axis is about 60°.

Preferred Embodiment 2

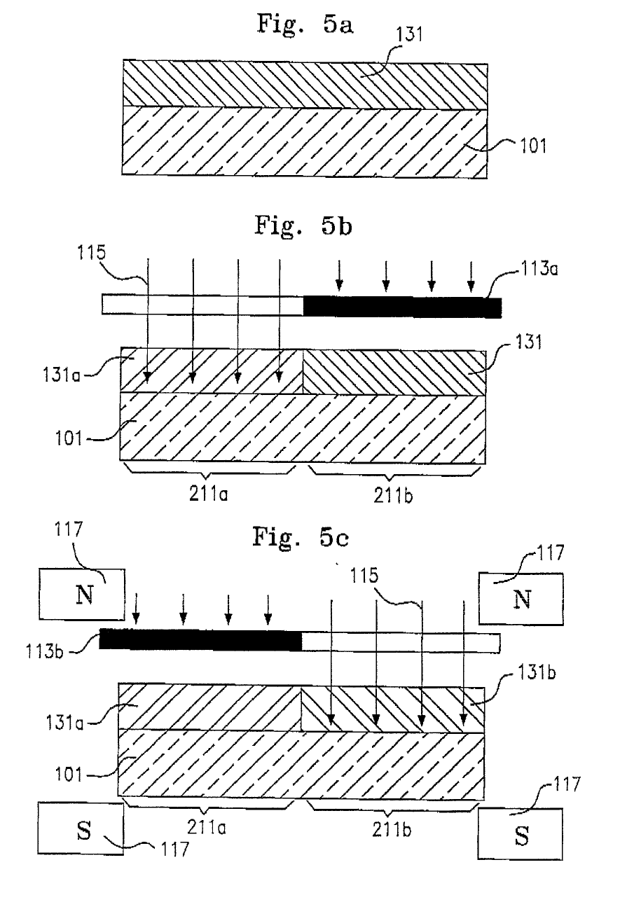

FIGS. 5a to 5c show another example of forming a magnetic material having dual easy axis by an ion beam treating. In this preferred embodiment, the magnetic material has at least one of ferromagnetic materials such as Co, Fe, and Ni. The ion beam treating the ferromagnetic material includes a selected one among inert gases such as He, Ne, Ar, Xe and Kr.

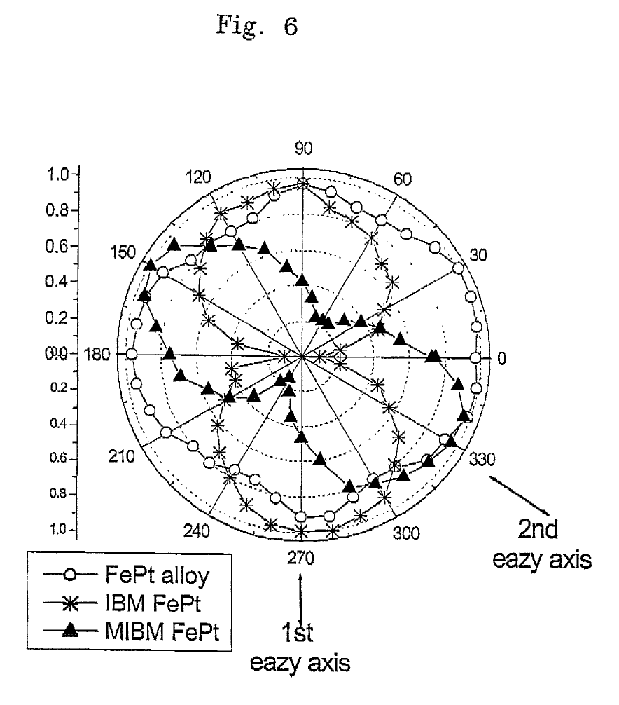

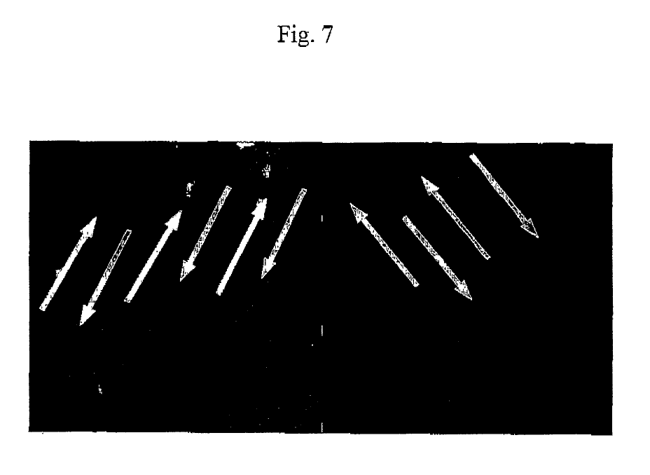

Referring to FIG. 5a, a FePt (or CoPt, NiPt) is deposited on a substrate 101 to form a magnetic (or ferromagnetic) layer 131 with the thickness of 20-100 nm in a vacuum chamber (not shown) with 8×10⁻⁷ torr. There is no easy axis in the magnetic layer. As shown in FIG. 6, the white circles represent the FePt magnetic layer with no easy axis (it is the general case).

Referring to FIG. 5b, a first area 211a and a second area 211b are defined at the magnetic layer 131. The second area 211a is covered with a first mask 113a such as a stencil mask or a photo resist mask. An Ar⁺ ion beam 115 is injected into the first area 211a of the magnetic layer 131 using an ion beam generator (not shown) where the energy of the ion beam 115 is about 80 keV. Then a first magnetic layer 131a is formed in the fist area 211a with a first easy axis having the direction from about 90° to 270° in the polar coordinate system. As shown in FIG. 6, the asterisks represent the direction of the fist easy axis of the FePt magnetic layer 131a in the fist area 211a.

Next, the first area 211a of the magnetic layer 131 is covered with a second mask 113b (stencil mask or photo resist mask), A magnetic field is applied to the magnetic layer with the perpendicular direction to the plane of the magnetic layer using magnets 117. An Ar⁺ ion beam 115 is injected into the second area 211b of the magnetic layer using an ion beam generator (not shown) where the energy of the ion beam 115 is about 80 keV. Then a second magnetic layer 131b is formed in the second area 211b with a second easy axis having the direction from about 150° to 330° in the polar coordinate system. As shown in FIG. 6, the black triangles represent the direction of the second easy axis of the FePt magnetic layer 131b in the second area 211b. Therefore, according to FIGS. 5b and 6, the difference in the direction between the first and second easy axis is about 60°.

According to the present invention, a magnetic thin film including physical boundaries between bit cells is accomplished by forming the neighboring bit cells to have different easy axis. FIG. 7 shows a MFM (Magnetic Force Microscope) image of the fist and second areas of the magnetic film The arrows represent the direction of the easy axis. The angle between the direction of the first easy axis and that of the second easy axis is about 60°, as shown in FIGS. 4 and 6. In this case, the magnetic force between the neighboring areas of the first and second easy axis is related to the fact of cos60°(=0.6) so the exchange interaction between the first and second easy axis is reduced to 60%. The reason for the angle being about 60° is not known exactly but it Is presumed to be related with the hexagonal structure of CoPt alloy. If this is true, the FeAu or CoAu having a simple cubic structure may have almost 90°.

Preferred Embodiment 3

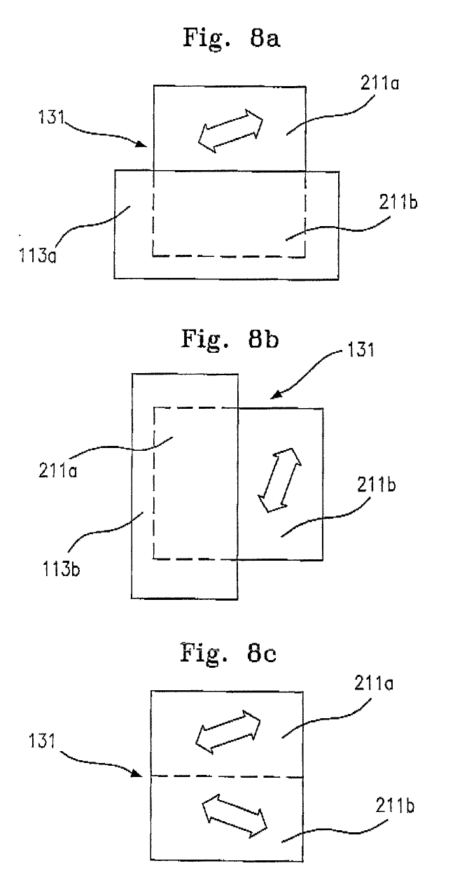

FIGS. 8a to 8c show the other example of forming a magnetic film having dual easy axis by ion beam treating without magnetic field. In this preferred embodiment, the magnetic material has at least one of ferromagnetic materials such as Co, Fe, and Ni. The ion beam treated ferromagnetic material includes a selected one among inert gases such as He, Ne, Ar, Xe and Kr.

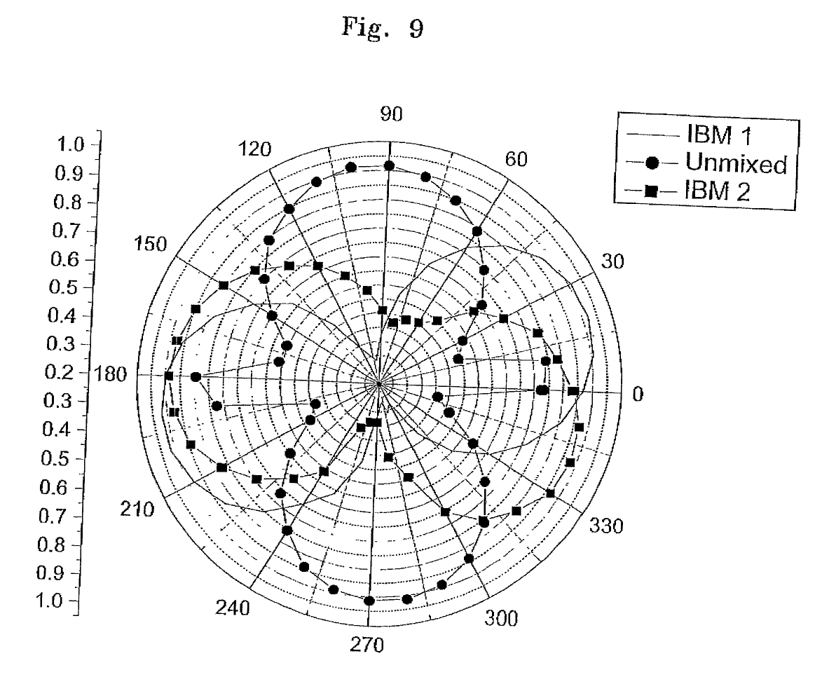

A magnetic material (FePt or CoPt, NiPt) is deposited on a substrate (not shown) to form a magnetic (or ferromagnetic) layer 131 with the thickness of 20-100 nm in a vacuum chamber (not shown) with 8×10⁻⁷ torr. There is no easy axis in the magnetic layer Here, an easy axis which is formed along the direction of 100°-280° in the polar coordinate system and which is in the Co/Pt layer is detected As shown in FIG. 9, the black circles represent the direction of the easy axis of the CoPt magnetic layer,

Referring to FIG. 8a, a first area 211a and a second area 211b are defined at the magnetic layer 131. The second area 211b is covered with a first mask 113a such as a stencil mask or a photo resist mask. An Ar⁺ ion beam is injected into the first area 211a of the magnetic layer 131 using an ion beam generator (not shown) in which the energy of the ion beam is about 80 keV. Then a first easy axis having the direction from about 20° to 200° in the polar coordinate system is formed in the first area 211a. The arrow mark represents the direction of the easy axis. As shown in FIG. 9, the normal line represents the direction of the first easy axis of the magnetic layer 131.

Next, the magnetic layer 131 is set to rotate in about 90° in counter clockwise direction, referring to FIG. 8b. The first area 211a of the magnetic layer 131 is covered with a second mask 113b (stencil mask or photo resist mask), An Ar⁺ ion beam is injected into the second area 211b of the magnetic layer 131 using an ion beam generator (not shown) in which the energy of the ion beam is about 80 keV. Then a second easy axis having the direction from about 160° to 340° in the polar coordinate system is formed in the second area 211b. The arrow mark represents the direction of the easy axis, As shown in FIG. 9, the black squares represent the direction of the second easy axis of the magnetic layer 131 in the second area 211b. Therefore, the difference in the direction between the first and second easy axis is about 40°.

Finally, the magnetic layer 131 has two areas, the first area 211a and the second area 211b. Each area has different magnetic easy axis referring to the FIG. 8c. In this embodiment, making of dual easy axis in one magnetic film in which the ion beam treatment is used in different setting of the magnetic film without magnetic field is shown. Therefore, a magnetic thin film can have multi easy axis by controlling the geometric condition of the ion treatment.

In conclusion, the present invention suggests a magnetic rum (or area) having one easy axis so that the magnetic film (or area) allows its magnetization to one or the other of two magnetization values which differs in magnetization vector directions and which has substantially equal magnetization vector magnitude in the absence of an external magnetic field. In this invention, the easy axis is formed neither by single-domain construction nor by shape anisotropy, but formed by ion treatment, Therefore, by adjusting the condition of ion treatment, the diction of the easy axis can be controlled freely, Furthermore, the present invention suggests a magnetic thin film having neighboring areas in which the easy axis is in different directions and in which the physical boundaries are formed. As a result, the magnetic property of one area does not influence that of the neighboring area Applying the present invention to the conventional magnetic storage device, the areal density can be increased and more advanced storage device can be realized.

What is claimed is:

1. A magnetic film comprising
an easy axis in a predetermined area treated by an ion beam.

2. A magnetic film comprising:
a first area having a fist easy axis with a fist direction; and
a second area having a second easy axis with a second direction.

3. The magnetic film of claim 2 wherein the angle difference between the direction of the first easy axis and the direction of the second easy axis is from 60° to 90°.

4. The magnetic film of claim 2 wherein the magnetic film includes an earth rare material which is at least selected one of Pt, Pd, Au and Tb.

5. The magnetic film of claim 2 wherein the magnetic film includes a transition metal which is a least selected one of Co, Ni, and Fe.

6. A method of manufacturing a magnetic film comprising steps of:
forming a magnetic layer on a substrate;
defining a fist area and a second area of the magnetic layer;
treating the first area of the magnetic layer with an ion beam to form a first easy axis having a first direction; and
treating the second area of the magnetic layer with an ion beam in a magnetic field to form a second easy axis having a second direction.

7. The method of manufacturing a magnetic film of claim 6 wherein the magnetic layer comprises an earth rare material selected at least one of Pt, Pd, Au and Tb.

8. The method of manufacturing a magnetic film of claim 6 wherein the angle difference between the direction of the fist easy axis and the direction of the second easy axis is from 60° to 90°.

9. The method of manufacturing a magnetic film of claim 6 wherein the magnetic layer comprises a transition metal elected at least one of Co, Ni and Fe.

10. The method of manufacturing a magnetic film of claim 6 wherein the ion beam comprises an inert gas selected at least one of He, Ne, Ar, Xe and Kr.

11. A method of manufacturing a magnetic film comprising steps of:
forming a magnetic layer on a substrate; and
applying an ion beam into a selected area of the magnetic layer to form a first easy axis having a first direction.

12. The method of manufacturing a magnetic Elm of claim 11 further comprising steps of:
applying a magnetic field to the magnetic film; and
applying an ion beam into another selected area of the magnetic layer to form a second easy axis having a second direction.

13. The method of manufacturing a magnetic film of claim 11 wherein the magnetic layer comprises a transition metal selected at least one of Co, Ni and Fe.

14. The method of manufacturing a magnetic film of claim 11 wherein the ion beam comprises an inert gas selected at least one of He, Ne, Ar, Xe and Kr.

15. A method of manufacturing a magnetic film comprising steps of,
form a magnetic layer on a substrate; and
treating the magnetic layer with an ion beam to form an easy axis having a direction.

16. The method of manufacturing a magnetic film of claim 15 wherein the magnetic layer comprises a transition metal selected at least one of Co, Ni and Fe.

17. A method of manufacturing a magnetic film comprising steps of.
forming a magnetic layer on a substrate;
applying a magnetic field to the magnetic film; and
treating the magnetic layer with an ion beam to form an easy axis having a direction.

18. The method of manufacturing a magnetic film of claim 18 wherein the magnetic layer comprises a transition metal selected at least one of Co, Ni and Pe.

19. A method of manufacturing a magnetic film comprising steps of:
forming a magnetic layer on a substrate;
covering the magnetic layer with a first mask opening a first area;
treating the first area with an ion beam to form a first easy axis;
rotating the magnetic layer in some degree;
covering the magnetic layer with a second mask opening a second area; and
treating the second area with the ion beam to form a second easy axis.

20. A method of manufacturing a magnetic film comprising steps of:
forming a magnetic layer on a substrate;
covering the magnetic layer with a first mask opening a first area;
treating the first area with an ion beam in a magnetic field to form a first easy axis;
rotating the magnetic layer in some degree;
covering the magnetic layer with a second mask opening a second area; and
treating the second area with the ion beam in the magnetic field to form a second easy axis.
